(19) United States
(12) Patent Application Publication
(10) Pub. No.: US 2017/0288101 A1
(43) Pub. Date: Oct. 5, 2017

(54) LED EMISSION SOURCE FOR SEQUENTIAL DRIVERS

(71) Applicant: Yuriy Borisovich Sokolov, Fryazino (RU)

(72) Inventor: Yuriy Borisovich Sokolov, Fryazino (RU)

(21) Appl. No.: 15/282,356

(22) Filed: Sep. 30, 2016

(30) Foreign Application Priority Data
Apr. 4, 2016 (RU) 2016112570

(51) Int. Cl. H01L 33/62; H01L 33/64

(52) U.S. Cl. CPC H01L 33/62; H01L 33/642

(57) ABSTRACT

An LED emission source is described herein. While the LED emission source can include any suitable component, in some implementations it includes a substrate that includes an insulating heat conducting material. In some cases, the emission source further includes two or more LED crystal groups, multiple electrical contacts for a driver connection, with the electrical contacts being disposed at a front face of the substrate, and a metal heat radiator that includes a plate having a surface that includes a dielectric layer, wherein the dielectric layer is located on a back side of the metal heat radiator and is configured to provide heat exchange with the substrate, and wherein a number of the electrical contacts is one unit more than a number of the LED crystal groups. Other implementations are described.

### RELATED APPLICATIONS

This application claims priority to Russian Application 2016112570, filed Apr. 4, 2016, and entitled LED EMISSION SOURCE FOR SEQUENTIAL DRIVERS, which is incorporated herein in its entirety by reference.

### FIELD

In accordance with some implementations, the described systems and methods relate to illumination engineering and are designed to be used with non-insulated power sources.

### BACKGROUND

Widespread LEDs, produced according to Chip-On-Board technology(COB), have two outputs at the front face of a ceramic substrate and are designed for operation with 18V to 70 V voltage, depending on power, but are not suitable for simple and low-budget sequential (non-insulated) drivers (power source), galvanically connected with the industrial supply network.

On the other hand, to ensure safety with some sequential power source galvanic connections for use with an industrial network, it may be necessary to insulate the whole board with COB. With a glance to standards, obligating to ensure insulation not less than 3.5 kW, it is very hard to realize, because the general board should be compactly located at the radiator, which in turn should contact with air for heat emission. Otherwise in case of printed-circuit board disruption, all metal parts are subject to mains voltage.

There is a COB, which distinctive feature is in the fact that sequentially connected emission sources are set directly at a well-conducting aluminum substrate, and to transfer the excess of heat, the side surface of aluminum substrate is used, connected with the radiator by a heat conducting lubricant. (CITIZEN ELECTRONICS CO., LTD, http://ce.citizen.co.jp., Catalogue <<Heat Dissipation Design>>, p.2).

Some known devices are not available to build illuminators at powerful COBs, because they emit substantially more thermal energy, which can be impossible to discharge through the side surface of the aluminum substrate to the radiator. Another disadvantage of the known devices is the risk of using economically sound sequential drivers, non-insulated from the industrial power supply network, when there is no reliable insulation between current-carrying elements of the substrate and radiator.

There is an LED lamp currently in use, designed for connection to industrial power supply network with voltage more than 120V via sequential (non-insulated) power source. Emission sources are installed at a PCB-aboard, located at a metal heat radiator, situated with a possibility of heat exchange at a metal radiator. Terminal leads, made at a back side of the board, provided with an insulating layer, impede effective heat exchange with metal heat radiator (KR1020160007998, MK [symbol] F21V25/00, published 21 Jan. 2016).

There is a device, containing emission sources, grouped in sequentially connected COB clusters, located at a ceramic substrate, a back side of which is covered by an insulating layer, where electric contacts are located. (CN100420019 C, MK [symbol] HO1L25/075, published CN1702862 on 30 Nov. 2005).

Such a device is designed to be used for networks with voltage level of 9-10 V and is not suitable to be used with sequential (non-insulated) power sources with networks with 200-300 V voltage, because of insufficient insulation of current-carrying elements.

### SUMMARY

One technical issue of the claimed device is improving of emission sources cooling and increase of electrical safety of the device, in case of using sequential drivers.

Some embodiments of the claimed invention are characterized by the following complex of features:

An LED emission source, containing a substrate comprising an insulating heat conducting material; two or more groups of LED crystals and contacts for one or more driver connections, installed at a front side of the substrate; a metal heat radiator comprising a plate, a surface of which is covered with a dielectric layer, where a back side of the dielectric layer is located with a possibility of heat exchange, and a quantity of the contacts is by one unit more, than a quantity of the LED crystals.

As the insulating heat conducting material of substrate ceramics is selected, breakdown voltage of which is not less than 4 kW, and a distance from any heat conducting element of the substrate up to its edge should be not less than 3 mm.

In accordance with some embodiments, the dielectric layer of the heat radiator plate is formed by a heat conducting prepreg, breakdown voltage of which is selected not worse than 4 kW.

In accordance with some embodiments, the total number of LED crystals, located at the substrate, should be selected, depending on the possibility of connection to the feeding contacts of general voltage up to 300 V.

### BRIEF DESCRIPTION OF THE DRAWINGS

FIG. 1 shows a plan view of a representative embodiment of the claimed device;

FIGS. 2-3 each show a side elevation view of a representative embodiment of the claimed device;

FIG. 4 illustrates a front perspective view of a representative embodiment of the claimed device; and

FIG. 5 illustrates a back perspective view of a representative embodiment of the claimed device.

### DETAILED DESCRIPTION

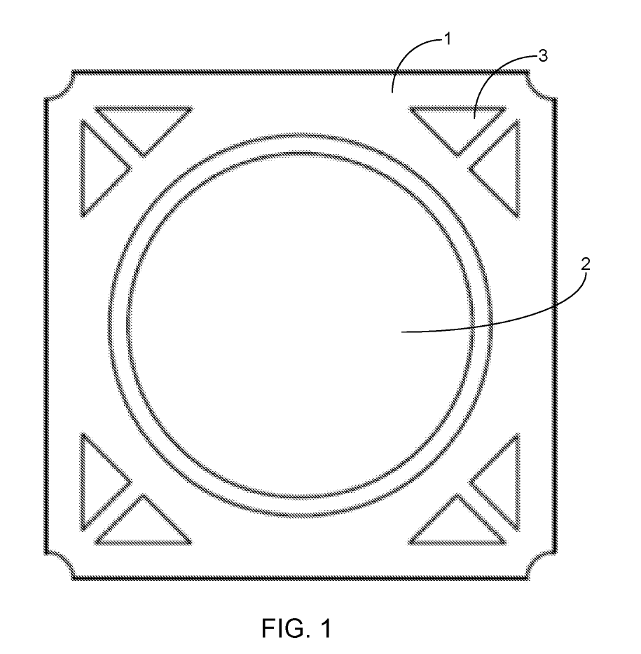

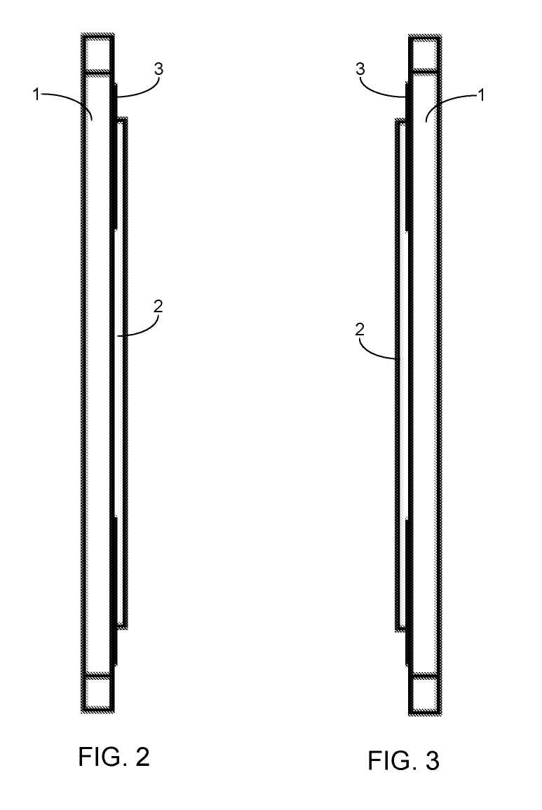

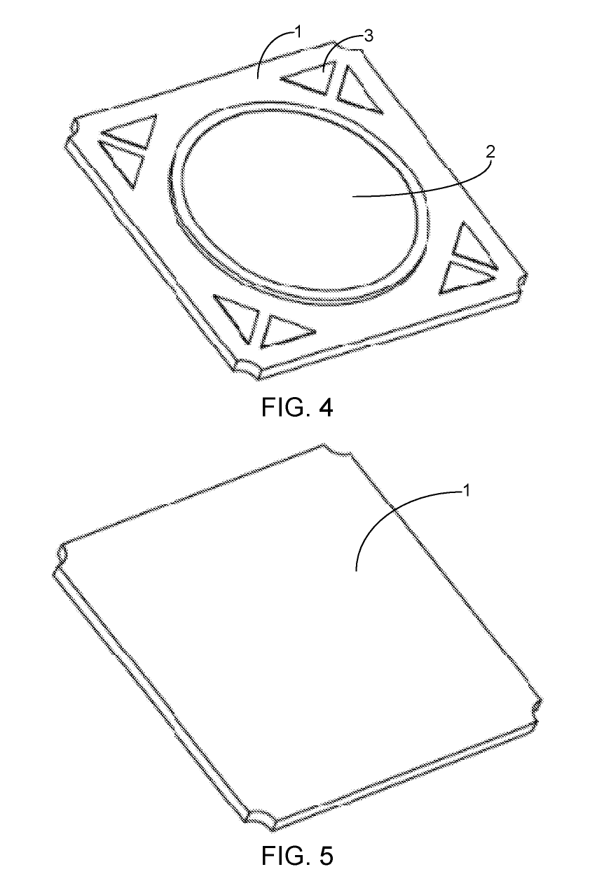

In FIGS. 1-5 elements of the claimed device are marked as follows:

1. Substrate.

2. LED groups field of location.

3. Electrical contacts.

In accordance with at least some embodiments, the described LED emission source for sequential drivers contains a substrate 1 made of an insulating heat conducting material (for example, one or more ceramics), two or more LED crystal groups and electrical contacts 3 for a driver connection (not shown), installed at a front surface of the substrate 1. In accordance with some embodiments, a back side of the substrate does not have elements of construction, impeding creation of a reliable heat contact with a surface of a metal heat radiator dielectric layer.

In some embodiments, the quantity of sequentially connected LED crystals in groups is selected with a glance to the possibility of connection to the electric contacts of general voltage up to 300 V. The number of electrical contacts 3 is determined (in some embodiments), depending on the number of LED crystal groups. For example, for six LED crystal groups at the surface of substrate 1 seven contacts 3 are located, for eight LED groups-nine contacts, i.e., contacts are more by one unit in comparison to the number of LED crystal groups. In some embodiments, such a proportion allows for a decrease of harmonic distortions, appearing in the electric network during LED groups feeding from sequential drivers.

In accordance with some embodiments, contacts 3 are located at a distance not less than 3 mm from an edge of substrate 1 to decrease the danger of breakdown at the metal heat radiator (not shown).

To increase the extent of insulation along the edge of substrate 1, some embodiments include an insulation collar, for example, made of silicon.

While the described device can be used in any suitable manner, in some embodiments, the described utility model may be realized on the basis of existing materials and assembly techniques of LED illuminating units.

We claim:

1. An LED emission source, comprising:
a substrate, comprising an insulating heat conducting material;
two or more LED crystal groups;
electrical contacts for a driver connection, the electrical contacts being disposed at a front face of the substrate; and
a metal heat radiator comprising a plate having a surface that comprises a dielectric layer,
wherein the dielectric layer is located on a back side of the metal heat radiator and is configured to provide heat exchange with the substrate, and
wherein a number of the electrical contacts is one unit more than a number of the LED crystal groups.

2. The LED emission source according to claim 1, wherein the insulating heat conducting material of the substrate comprises a ceramic having a breakdown voltage that is not less than 4 kW.

3. The LED emission source according to claim 1, wherein the dielectric layer comprises a heat conducting prepreg having a breakdown voltage that is not worse than 4 kW.

4. The LED emission source according to claim 1, wherein a distance from any current-carrying element of the substrate to an edge of the substrate is not less than 3 mm.

5. The LED emission source according to claim 1, wherein a number of sequentially connected LED crystal groups is selected for use on the substrate with a connection to the contacts where general voltage supplied to the substrate is up to 300 V.

6. The LED emission source according to claim 1, wherein the substrate further comprises an insulation collar.
